(19) United States
(12) Patent Application Publication
(10) Pub. No.: US 2014/0145773 A1
(43) Pub. Date: May 29, 2014

(54) SEMICONDUCTOR INTEGRATED CIRCUIT HAVING BACK-GATE-VOLTAGE CONTROL CIRCUIT

(71) Applicant: FUJITSU LIMITED, Kawasaki-shi (JP)

(72) Inventor: Yasuhiro HASHIMOTO, Yokohama (JP)

(73) Assignee: FUJITSU LIMITED, Kawasaki-shi (JP)

(21) Appl. No.: 14/169,186

(22) Filed: Jan. 31, 2014

Related U.S. Application Data
(63) Continuation of application No. PCT/JP2011/067801, filed on Aug. 3, 2011.

(51) Int. Cl. H03K 3/012

(52) U.S. Cl. CPC H03K 3/012
USPC 327/218

(57) ABSTRACT

A semiconductor integrated circuit includes a latch circuit, a data applying circuit configured to apply data to an input node of the latch circuit at timing responsive to a synchronizing signal, and a back-gate-voltage control circuit configured to change a back-gate voltage of at least one transistor in an inverter included in the latch circuit at timing responsive to the synchronizing signal.

### CROSS-REFERENCE TO RELATED APPLICATIONS

This application is a continuation application of International Application PCT/JP2011/067801 filed on Aug. 3, 2011 and designated the U.S., the entire contents of which are incorporated herein by reference.

### FIELD

The disclosures herein relate to a semiconductor integrated circuit.

### BACKGROUND

A latch circuit used in a logic circuit has two inverters which are connected to each other such that the respective outputs thereof are connected to the inputs of each other. Data driven by a strong drive force is supplied from an external source to the input of one of the inverters in synchronization with a clock signal or the like, thereby placing the inverters in the logic state responsive to the data. After this, data responsive to the input data is maintained by the cross connections of the inverters even in the absence of externally applied data.

With a recent progress in reducing the power supply voltage of integrated circuits, the threshold voltage of transistors has also been lowered (made smaller). For example, a threshold voltage VTH is set equal to about 0.7 V in the case of a power supply voltage VDD being 5 V, and a threshold voltage VTH is set equal to about 0.2 V in the case of a power supply voltage VDD being 1 V. Under the condition that a power supply voltage is low, a localized change may occur in a power supply voltage VDD or in a ground voltage VSS due to power supply noise while a latch circuit holds data. In such a case, the stabile state of the latch is lost, resulting in a reversal of the data.

In an example to be considered, a first inverter has a HIGH input and a LOW output, and a second inverter has a LOW input and a HIGH output. Each inverter has a PMOS transistor and an NMOS transistor that are series-connected. Upon a noise being introduced to the source node of the NMOS transistor of the first inverter to increase the source voltage thereof, the output potential of the first inverter, which is supposed to be LOW, ends up rising. As a result, the second inverter mistakenly detects a HIGH input for the input signal that is supposed to be LOW, and attempts to change the output thereof to LOW. When this happens, the power supply noise may disappear before the change to LOW of the output of the second inverter, i.e., the change to LOW of the input of the first inverter, exceeds the threshold of the PMOS transistor of the first inverter. In such a case, no problem occurs since the latch returns to its original state. However, the change to LOW of the output of the second inverter may exceed the threshold of the PMOS transistor of the first inverter, resulting in this PMOS transistor being turned on. In such a case, the output of the first inverter is changed to HIGH. The second inverter is then placed in the stable state with the output thereof being LOW. In this manner, the data of the latch is reversed.

Also, under the condition that the first inverter has a LOW input and a HIGH output, and that the second inverter has a HIGH input and a LOW output, noise may be introduced to the source node of the PMOS transistor of the first inverter, thereby lowing the source voltage. In this case also, the data of the latch may be reversed.

Such a reversal of latch data may occur during the read-operation period in which no external data is being applied. During the write-operation period in which external data is being applied, the application of data by a drive force of an external signal source stronger than the drive force of the second inverter ensures that the input node of the first inverter is not inverted. Namely, no reversal of latch data occurs during the write-operation period in which external data is being applied.

The technology disclosed in Patent Document 1 controls a back-gate voltage by use of a clock signal in order to reduce power consumption in a MOS-DRAM. This document describes that the control of a back-gate voltage using a clock signal may also be used for MOS-FET in general. The control of a back-gate voltage disclosed in this document, however, is directed to reduction in power consumption. There is no disclosure of back-gate-voltage control that is suitable for increasing tolerance to power supply noise.

### [Patent Document 1] Japanese Laid-open Patent Publication No. 8-17183

### SUMMARY

According to an aspect of the embodiment, a semiconductor integrated circuit includes a latch circuit, a data applying circuit configured to apply data to an input node of the latch circuit at timing responsive to a synchronizing signal, and a back-gate-voltage control circuit configured to change a back-gate voltage of at least one transistor in an inverter included in the latch circuit at timing responsive to the synchronizing signal.

A method of driving a latch circuit includes applying data to an input node of a latch circuit at timing responsive to a synchronizing signal, and changing a back-gate voltage of at least one transistor in an inverter included in the latch circuit at timing responsive to the synchronizing signal.

The object and advantages of the embodiment will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIG. 1 is a drawing illustrating an example of the configuration of a semiconductor integrated circuit;

FIG. 2 is a drawing illustrating an example of the configuration of a back-gate-voltage control circuit;

FIG. 3 is a drawing illustrating an example of the operation of the semiconductor integrated circuit illustrated in FIG. 1;

FIG. 4 is a drawing illustrating the configuration of a circuit that is used in computer simulation;

FIG. 5 is a drawing illustrating the conditions and results of the computer simulation;

FIG. 6 is a drawing illustrating signal waveforms of the computer simulation;

FIG. 7 is an enlarged view of waveforms in the case of back-gate-voltage control being used and waveforms in the case of back-gate-voltage control being not used;

FIG. 8 is a drawing illustrating a specific example of the configuration of the semiconductor integrated circuit illustrated in FIG. 1;

FIG. 9 is a drawing illustrating a specific example of the circuit configuration of the semiconductor integrated circuit illustrated in FIG. 8;

FIG. 10 is a drawing illustrating a variation of the configuration of the semiconductor integrated circuit illustrated in FIG. 1;

FIG. 11 is a drawing illustrating a variation of the configuration of the back-gate-voltage control circuit;

FIG. 12 is a drawing illustrating an example of the operation of the semiconductor integrated circuit illustrated in FIG. 1 when the back-gate-voltage control circuit is used;

FIG. 13 is a drawing illustrating another example of the operation of the semiconductor integrated circuit illustrated in FIG. 1 when the back-gate-voltage control circuit is used;

FIG. 14 is a drawing illustrating a specific example of the circuit configuration when the back-gate-voltage control circuit illustrated in FIG. 11 is used in FIG. 1;

FIG. 15 is a drawing illustrating a variation of the semiconductor integrated circuit illustrated in FIG. 8;

FIG. 16 is a drawing illustrating an example of the operation of the semiconductor integrated circuit illustrated in FIG. 15;

FIG. 17 is a drawing illustrating another variation of the semiconductor integrated circuit illustrated in FIG. 8;

FIG. 18 is a drawing illustrating a specific example of the circuit configuration of the semiconductor integrated circuit illustrated in FIG. 17;

FIG. 19 is a drawing illustrating an example of the configuration of the semiconductor integrated circuit in which a Dice latch is used as the latch circuit;

FIG. 20 is a drawing illustrating an example of the configuration of a variation of the semiconductor integrated circuit illustrated in FIG. 1;

FIG. 21 is a drawing illustrating a triple-well structure and a twin-well structure in comparison with each other;

FIG. 22 is a drawing illustrating an example of the configuration of a chopper circuit;

FIG. 23 is a drawing illustrating an example of the operation of the chopper circuit illustrated in FIG. 22;

FIG. 24 is a drawing illustrating another example of the operation of the chopper circuit illustrated in FIG. 22;

FIG. 25 is a drawing illustrating another example of the configuration of a chopper circuit;

FIG. 26 is a drawing illustrating an example of the operation of the chopper circuit illustrated in FIG. 25;

FIG. 27 is a drawing illustrating another example of the operation of the chopper circuit illustrated in FIG. 25;

FIG. 28 is a drawing illustrating an example of the configuration in which back-gate-voltage control is applied to a plurality of latch circuits; and

FIG. 29 is a drawing illustrating another example of the configuration in which back-gate-voltage control is applied to a plurality of latch circuits.

### DESCRIPTION OF EMBODIMENTS

In the following, embodiments of the invention will be described with reference to the accompanying drawings.

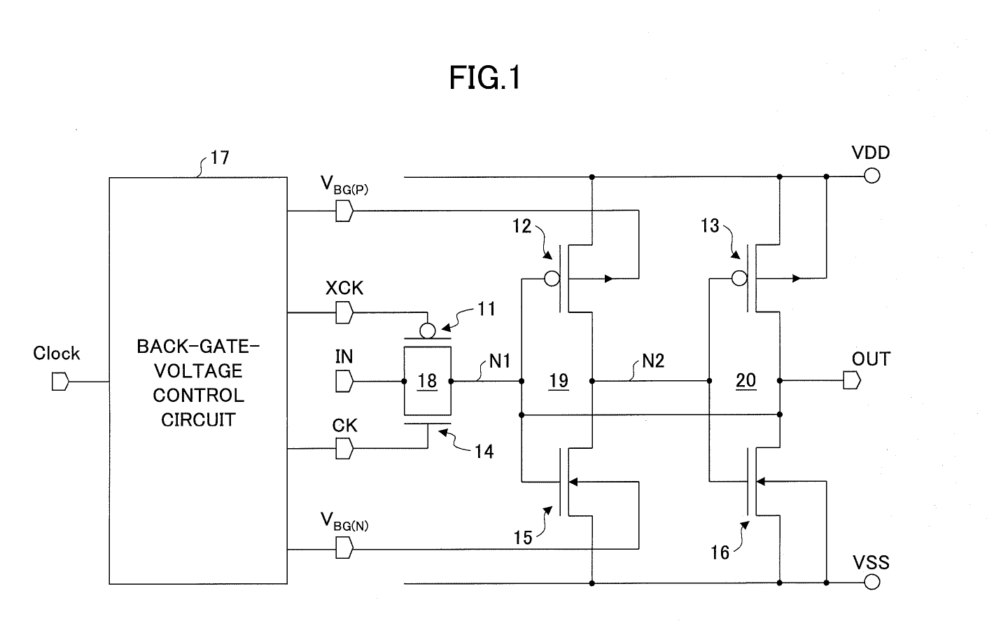

FIG. 1 is a drawing illustrating an example of the configuration of a semiconductor integrated circuit. The semiconductor integrated circuit illustrated in FIG. 1 includes PMOS transistors 11 through 13, NMOS transistors 14 through 16, and a back-gate-voltage control circuit 17. The PMOS transistor 12 and the NMOS transistor 15 function as a first inverter 19, and the PMOS transistor 13 and the NMOS transistor 16 function as a second inverter 20. The first inverter 19 and the second inverter 20 together function as a latch circuit. The first inverter 19 has an input thereof connected to a first node N1 and an output thereof connected to a second node N2. The second inverter 20 has an input thereof connected to the second node N2 and an output thereof connected to the first node N1. The output of the second inverter 20 is also connected to an output node OUT. The second inverter 20 is used as a keeper for the first inverter 19. In general, the second inverter 20 is configured to have a drive force that is weaker than the drive force of the first inverter 19.

The PMOS transistor 11 and the NMOS transistor 14 are connected in parallel to each other to serve as a transmission gate 18. The transmission gate 18 serves as a data applying circuit that applies data to the input node N1 of the latch circuit at the timing responsive to a synchronizing signal Clock. The back-gate-voltage control circuit 17 applies transfer control signals XCK and CK responsive to the synchronizing signal Clock to the PMOS transistor 11 and the NMOS transistor 14.

The back-gate-voltage control circuit 17 further changes the back-gate voltage of at least one transistor in the inverters included in the latch circuit at the timing responsive to the synchronizing signal Clock. In the example illustrated in FIG. 1, such at least one transistor includes the PMOS transistor 12 and the NMOS transistor 15 which are included in the first inverter 19 and which have the gate nodes thereof connected to the first node N1 and the drain nodes thereof connected to the second node N2. The back-gate-voltage control circuit 17 applies a back-gate voltage V_{BG(P)} to the back gate of the PMOS transistor 12, and applies a back-gate voltage V_{BG(N)} to the back gate of the NMOS transistor 15.

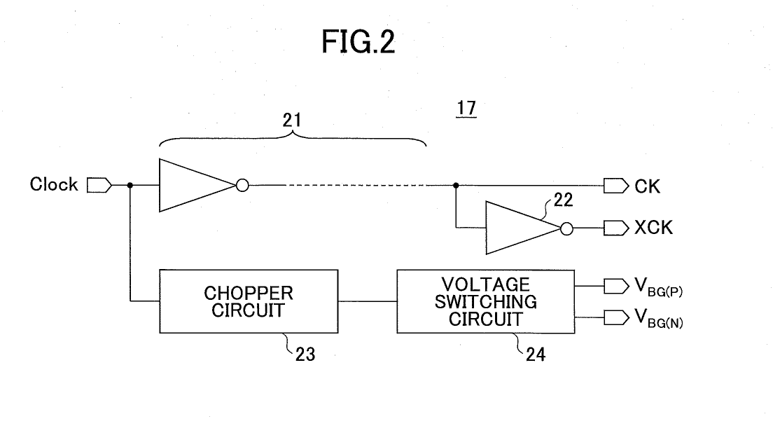

FIG. 2 is a drawing illustrating an example of the configuration of the back-gate-voltage control circuit 17. The back-gate-voltage control circuit 17 includes one or more inverters 21, an inverter 22, a chopper circuit 23, and a voltage switching circuit 24. The chopper circuit 23 receives the synchronizing signal (clock signal) Clock alternating between a HIGH period and a LOW period that have the same constant length, and generates a pulse signal having a HIGH period shorter than the HIGH period of the synchronizing signal Clock and having a remaining LOW period. The voltage switching circuit 24 maintains the back-gate voltages V_{BG(P)} and V_{BG(N)} at a first voltage during the HIGH period of the pulse signal, and maintains the back-gate voltages V_{BG(P)} and V_{BG(N)} at a second voltage that is a reverse bias during the LOW period of the pulse signal. The one or more inverters 21 may be an even number of inverters, and delays the clock signal Clock by a time length responsive to the number of inverters for provision as the transfer control signal CK. The one or more inverters 21 are provided for the purpose of imposing a delay in order to provide a desired timing relationship between a change in the transfer control signal and a change in the back-gate voltage. The one or more inverters 21 may not be provided in some cases. The inverter 22 receives the transfer control signal CK, and outputs an inverse signal XCK of the transfer control signal CK.

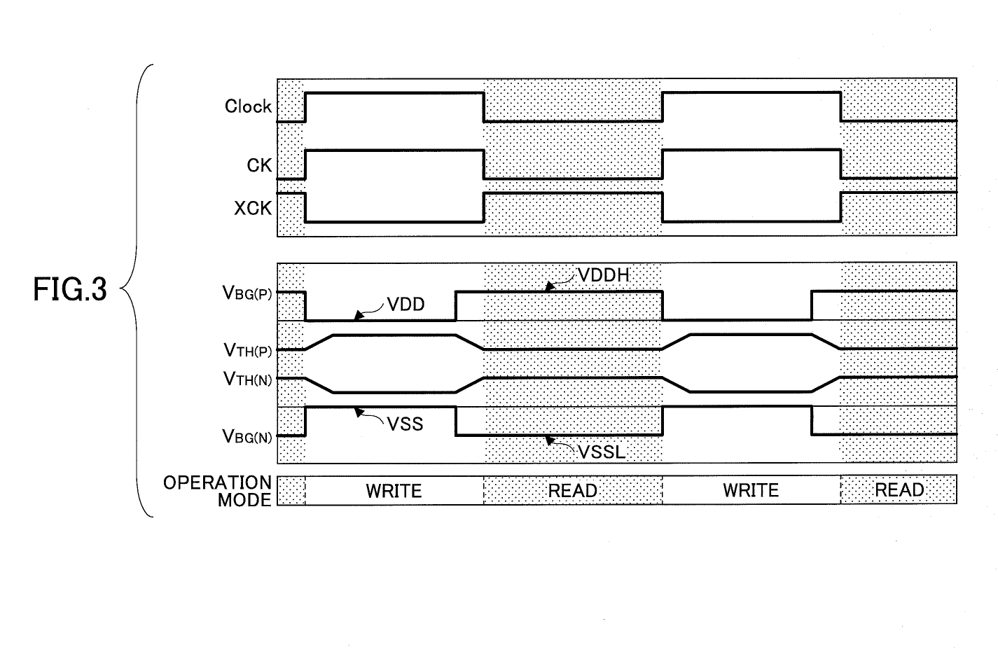

FIG. 3 is a drawing illustrating an example of the operation of the semiconductor integrated circuit illustrated in FIG. 1. FIG. 3 illustrates timing relationships when the one or more inverters 21 illustrated in FIG. 2 are not provided. In such timing relationships, the edge timing of the clock signal Clock and the edge timing of the transfer control signals CK and XCK are substantially the same. When the transfer control signals CK and XCK are HIGH and LOW, respectively, the transmission gate 18 illustrated in FIG. 1 is conductive to set the operation mode to a write mode. Namely, in this case, an input potential IN is supplied to the first node N1 through the transmission gate 18. As a result, the potential of the first node N1 is set equal to the input potential IN. The first inverter 19 generates an inverse potential of the input potential IN at the second node N2 in response to the potential of the first node N1 that is equal to the input potential IN. The second inverter 20 generates a potential equal to the input potential IN at the output node OUT in response to the potential of the second node N2 that is equal to the inverse potential of the input potential IN. The output node OUT is connected to the first node N1. Accordingly, a state in which the first node N1 is at the input potential IN and the second node N2 is at the inverse potential of the input potential IN is maintained by the latch circuit as a stable state.

During the write operation period described above, the back-gate voltage V_{BG(P)} of the PMOS transistor 12 of the first inverter 19 is set equal to the power supply voltage VDD as illustrated in FIG. 3. Further, the back-gate voltage V_{BG(N)} of the NMOS transistor 15 of the first inverter 19 is set equal to the ground voltage VSS. Accordingly, the back-gate voltages of the PMOS transistor 12 and the NMOS transistor 15 are set equal to the source voltages of these respective transistors, so that threshold voltages V_{TH(P)} and V_{TH(N)} are set equal to the normal values thereof that are observed under no-bias-effect conditions.

When the transfer control signals CK and XCK are LOW and HIGH, respectively, the transmission gate 18 illustrated in FIG. 1 is nonconductive to set the operation mode to a read mode. Accordingly, a state in which, with the output potential OUT being at the output node, the first node N1 is equal to the output potential OUT, and the second node N2 is at the inverse potential of the output potential OUT is maintained by the latch circuit as a stable state. A circuit at the next following stage connected to the output node (e.g., another latch circuit or the like) reads the output potential OUT of the output node during the read period in which the transfer control signals CK and XCK are LOW and HIGH, respectively.

During the read operation period described above, the back-gate voltage V_{BG(P)} of the PMOS transistor 12 of the first inverter 19 is set equal to a voltage VDDH (>VDD) that is situated further to the positive side than the power supply voltage VDD, i.e., situated on the reverse-bias side relative to the power supply voltage VDD, as illustrated in FIG. 3. Further, the back-gate voltage V_{BG(N)} of the NMOS transistor 15 of the first inverter 19 is set equal to a voltage VSSL (<VSS) that is situated further to the negative side than the ground voltage VSS, i.e., situated on the reverse-bias side relative to the ground voltage VSS. Accordingly, the back-gate voltages of the PMOS transistor 12 and the NMOS transistor 15 are placed in the reverse-bias state, so that the threshold voltages V_{TH(P)} and V_{TH (N)} are increased by the bias effect (i.e., are set equal to voltages whose differences from the respective source potentials are increased).

In this manner, the back-gate voltage of a transistor in the first inverter 19 is reverse-biased to increase the threshold voltage of the transistor during the read-operation period of the latch circuit. Such an increase in the threshold voltage provided by a reverse bias during the read-operation period can increase tolerance to power supply noise during the read-operation period. Further, during the write-operation period of the latch circuit, the normal threshold voltage without a bias effect is used to provide a high-speed write operation. A data potential is applied by a large drive force of an external signal source during the write-operation period, so that the potential of the input node N1 of the first inverter 19 is not inverted by power supply noise. During such a period, thus, there is no need to apply a reverse bias to the back-gate voltage.

In general, the back-gate voltage may be kept at the source voltage during at least part of the write-operation period, and the back-gate voltage may be kept at the reverse-biased voltage during at least part of the read-operation period.

In the example illustrated in FIG. 3, the back-gate voltage is set equal to the source voltage during at least an early part of the write-operation period, and the back-gate voltage is changed from the source voltage to the reverse-biased voltage during the write-operation period. The back-gate voltage is kept at the reverse-biased voltage during all the read-operation period. This arrangement is made because the threshold voltage of a transistor does not change immediately in response to a change in the back-gate voltage of the transistor, and a slight delay is bound to occur. In order to improve tolerance to power supply noise during the read-operation period, it is preferable for the threshold voltage to be kept at an increased level over the entirety of the read-operation period. In consideration of this, the example illustrated in FIG. 3 is configured such that the time for applying the reverse-biased back-gate voltage is slightly earlier than the start time of a read-operation period.

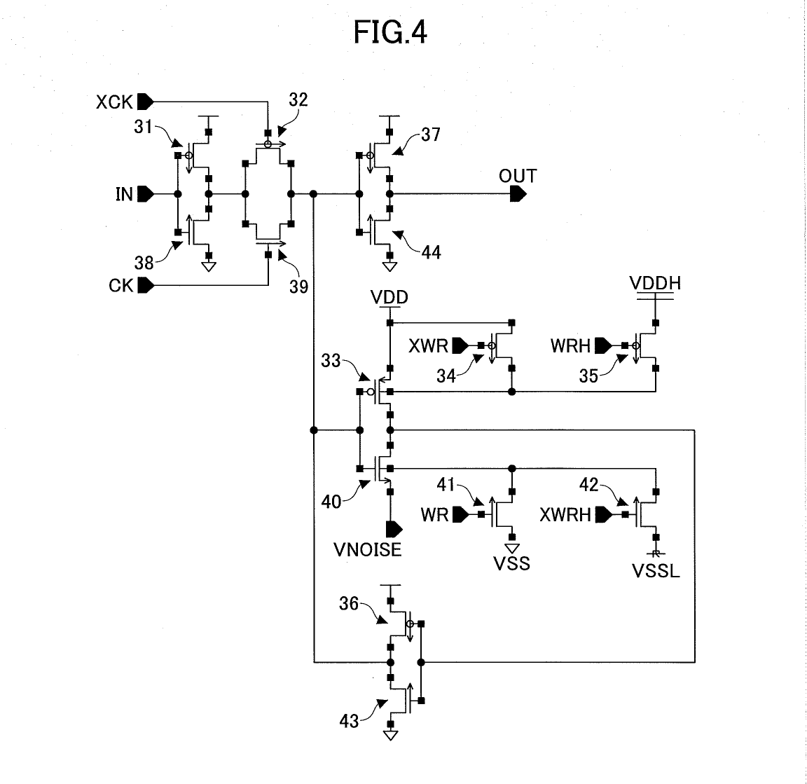

In the following, a description will be given of a computer simulation that demonstrates the effect of improvement in noise tolerance in the semiconductor integrated circuit illustrated in FIG. 1. FIG. 4 is a drawing illustrating the configuration of a circuit that is used in the computer simulation. The circuit used in the computer simulation includes PMOS transistors 31 through 37 and NMOS transistors 38 through 44. The PMOS transistor 32 and the NMOS transistor 39 are connected in parallel to each other to serve as a transmission gate. The PMOS transistor 33 and the NMOS transistor 40 together function as a first inverter. The PMOS transistor 36 and the NMOS transistor 43 together function as a second inverter. The PMOS transistors 34 and 35 are used to switch back-gate voltages of the PMOS transistor 33. The NMOS transistors 41 and 42 are used to switch back-gate voltages of the NMOS transistor 40. Gate potentials WR and XWRH of the respective NMOS transistors 41 and 42 are logically inverted from each other. Further, gate potentials XWR and WRH of the respective PMOS transistors 34 and 35 are logically inverted from each other. Moreover, WR and XWR are logically inverted from each other, and WRH and XWRH are logically inverted from each other. A power supply noise VNOISE is applied to the source node of the NMOS transistor 40. The PMOS transistor 37 and the NMOS transistor 44 together function as a data-output-purpose inverter.

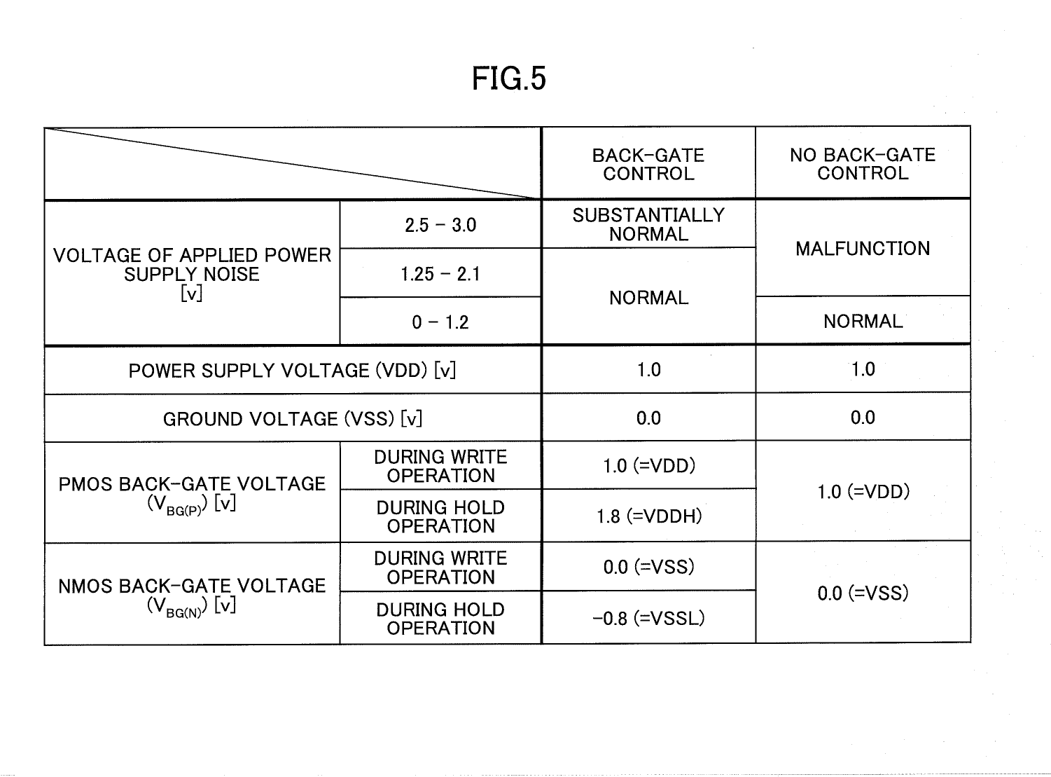

FIG. 5 is a drawing illustrating the conditions and results of the computer simulation. The power supply voltage is 1.0 V, and the ground voltage is 0.0 V. The back-gate voltage of the PMOS transistor 33 illustrated in FIG. 4 is set equal to source potential 1.0 V (i.e., the power supply voltage VDD) during the write operation, and is set equal to reverse-biased potential 1.8 V (i.e., VDDH) during the hold operation. The back-gate voltage of the NMOS transistor 40 illustrated in FIG. 4 is set equal to source potential 0.0 V (i.e., the ground voltage VSS) during the write operation, and is set equal to reverse-biased potential −0.8 V (i.e., VSSL) during the hold operation. For comparison purposes, further, the back-gate voltage of the PMOS transistor 33 is fixed to 1.0 V, and the back-gate voltage of the NMOS transistor 40 is fixed to 0.0 V. Results of such a simulation are illustrated under the title “NO BACK-GATE CONTROL”.

As illustrated in FIG. 5, in the base of no back-gate control, the latch circuit operates properly when the voltage of applied power supply noise is in the range of 0 V to 1.2 V, but the latch circuit exhibits malfunctioning when the voltage of applied power supply noise exceeds 1.25 V. In contrast, in the case of back-gate control, the latch circuit operates properly when the voltage of applied power supply noise is in a wide range of 0 V to 3.0 V.

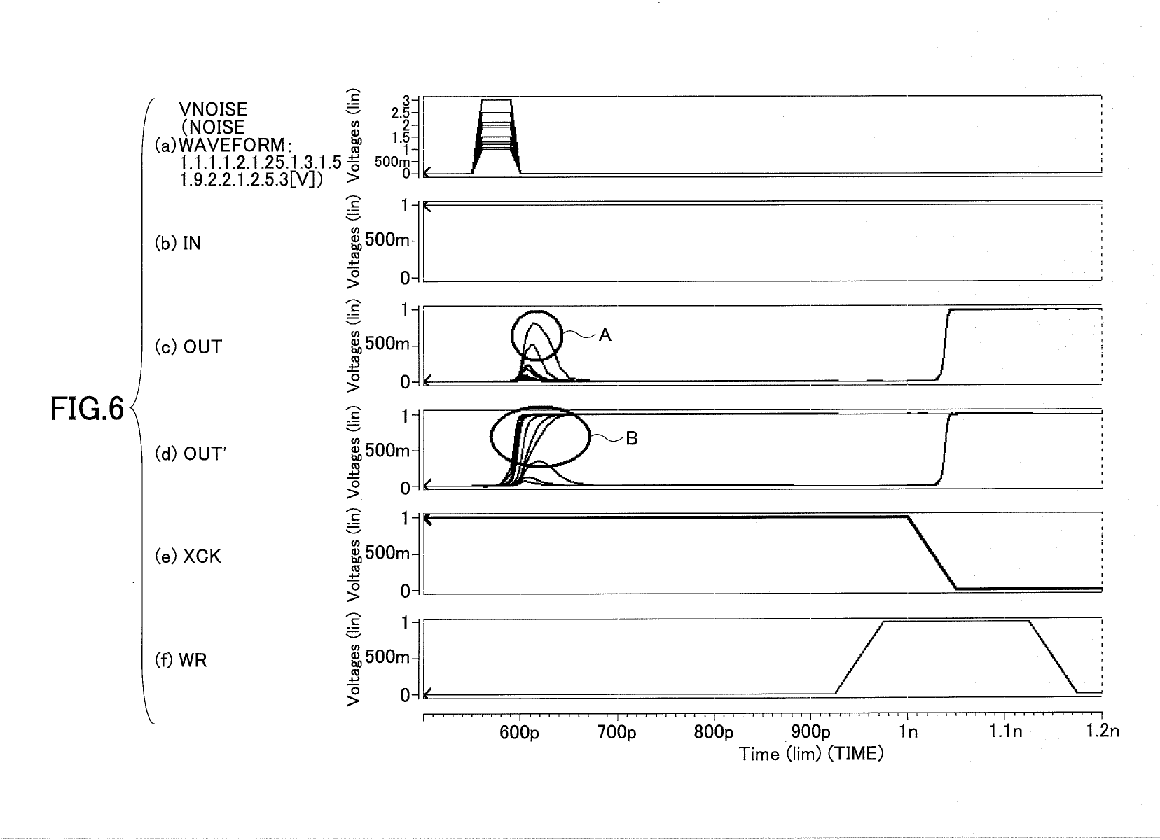

FIG. 6 is a drawing illustrating signal waveforms of the computer simulation. As can be seen in the waveform of the power supply noise VNOISE illustrated in FIG. 6-(a), the voltage (i.e., the source voltage of the NMOS transistor 40 illustrated in FIG. 4) that is normally 0.0 V temporarily rises to a predetermined voltage, and then returns to 0.0 V. The waveform of an input data voltage IN is illustrated in FIG. 6-(b). In this example, the input voltage is 1.0 V. FIG. 6-(c) illustrates changes in the output voltage OUT when back-gate-voltage control is used, and FIG. 6-(d) illustrates changes in the output voltage OUT' when back-gate-voltage control is not used. FIG. 6-(e) illustrates a change in the transfer control signal XCK. The HIGH (i.e., 1.0 V) period of XCK is the read-operation period, and the LOW (i.e., 0.0 V) period of XCK is the write-operation period. FIG. 6-(f) illustrates the back-gate voltage control signal WR (i.e., the gate voltage of the NMOS transistor 41 illustrated in FIG. 4). The back-gate voltage is reserve-biased during the LOW period of WR. The back-gate voltage is subjected to no bias (i.e., equal to the source voltage) during the HIGH period of WR.

In the case of back-gate-voltage control being used as illustrated in FIG. 6-(c), the output voltage OUT temporarily rises as illustrated in waveforms A in response to the power supply noise, but subsequently returns to an original voltage of 0.0 V. In the case of back-gate-voltage control being not used as illustrated in FIG. 6-(d), on the other hand, the output voltage OUT' rises as illustrated in waveforms B in response to the power supply noise, and then stays at an erroneous voltage of 1.0 V.

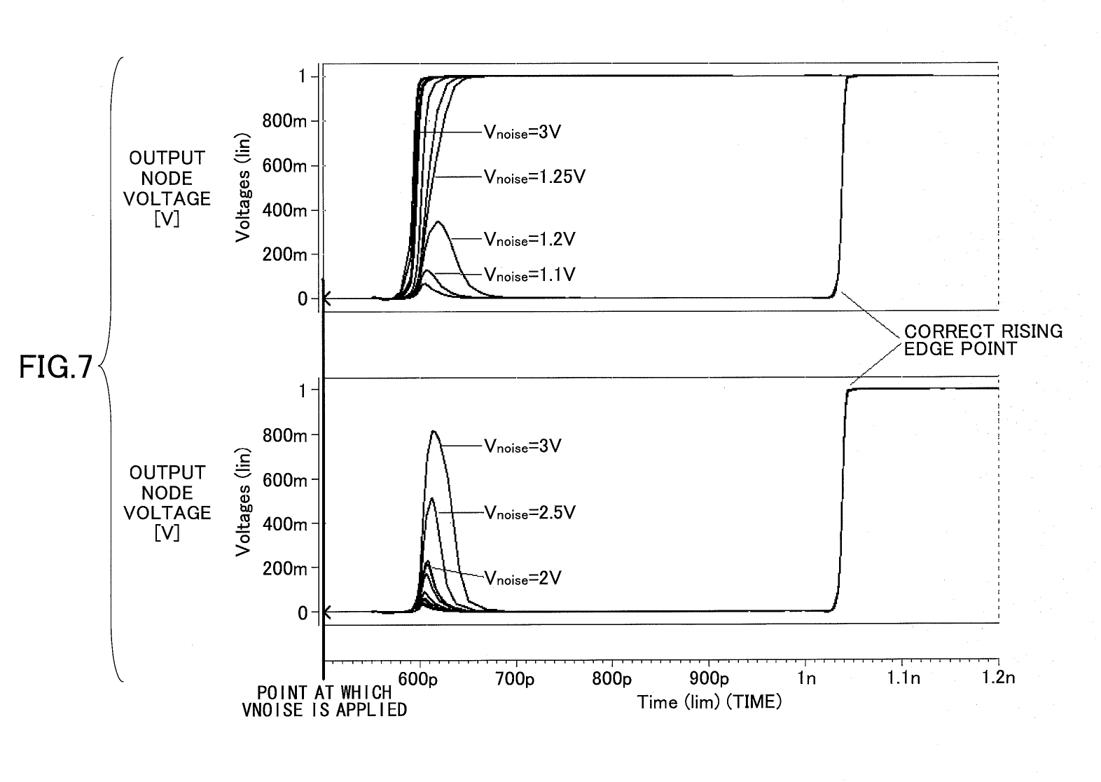

FIG. 7 is an enlarged view of the waveforms in the case of back-gate-voltage control being used and the waveforms in the case of back-gate-voltage control being not used. The upper row illustrates the waveforms in the case of back-gate-voltage control being not used, and the lower row illustrates the waveforms in the case of back-gate-voltage control being used. In the case of back-gate-voltage control being not used, the output voltage exhibits a temporal rise, but subsequently returns to its original voltage, i.e, to 0.0 V, as long as the power supply noise voltage VNOISE is up to 1.2 V. However, with the power supply noise voltage VNOISE being 1.25V or higher, the output voltage rises up to 1.0 V, and stays at that level. In the case of back-gate-voltage control being used, on the other hand, the output voltage exhibits a temporal rise, but subsequently returns to its original voltage, i.e, to 0.0 V, even when VNOISE is at a maximum of 3.0 V.

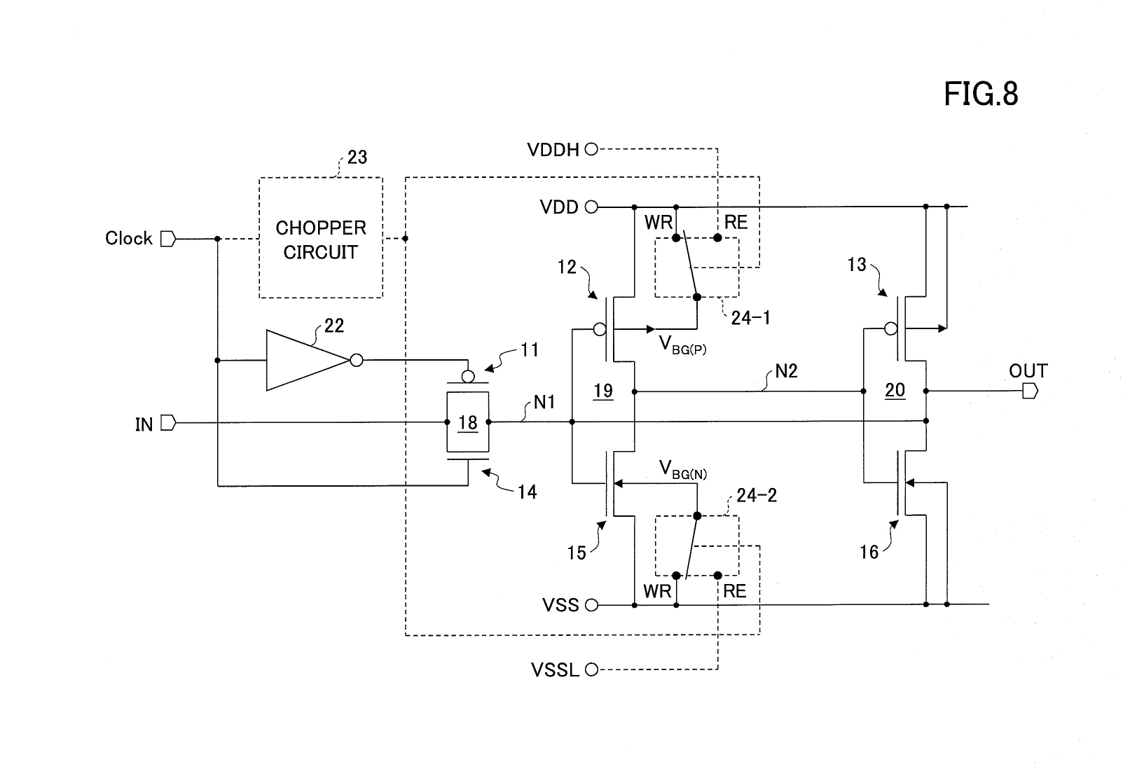

FIG. 8 is a drawing illustrating a specific example of the configuration of the semiconductor integrated circuit illustrated in FIG. 1. In FIG. 8, the same or corresponding elements as those of FIG. 1 and FIG. 2 are referred to by the same or corresponding numerals, and a description thereof will be omitted as appropriate. In the semiconductor integrated circuit illustrated in FIG. 8, the back-gate-voltage control circuit 17 of FIG. 1 is replaced with the inverter 22, the chopper circuit 23, and the voltage switching circuits 24-1 and 24-2, some of which are illustrated in FIG. 2. In FIG. 8, the one or more inverters 21 illustrated in FIG. 2 are not provided.

In the semiconductor integrated circuit illustrated in FIG. 8, connections in the voltage switching circuits 24-1 and 24-2 that are switch circuits are changed in response to signals supplied from the chopper circuit 23, resulting in the back-gate voltages being changed. The back-gate voltage V_{BG(P)} of the PMOS transistor 12 is set equal to VDD by the switch circuit 24-1 during the write operation, and is set equal to VDDH (>VDD) during the read operation. The back-gate voltage V_{BG(N)} of the NMOS transistor 15 is set equal to VSS by the switch circuit 24-2 during the write operation, and is set equal to VSSL (<VSS) during the read operation.

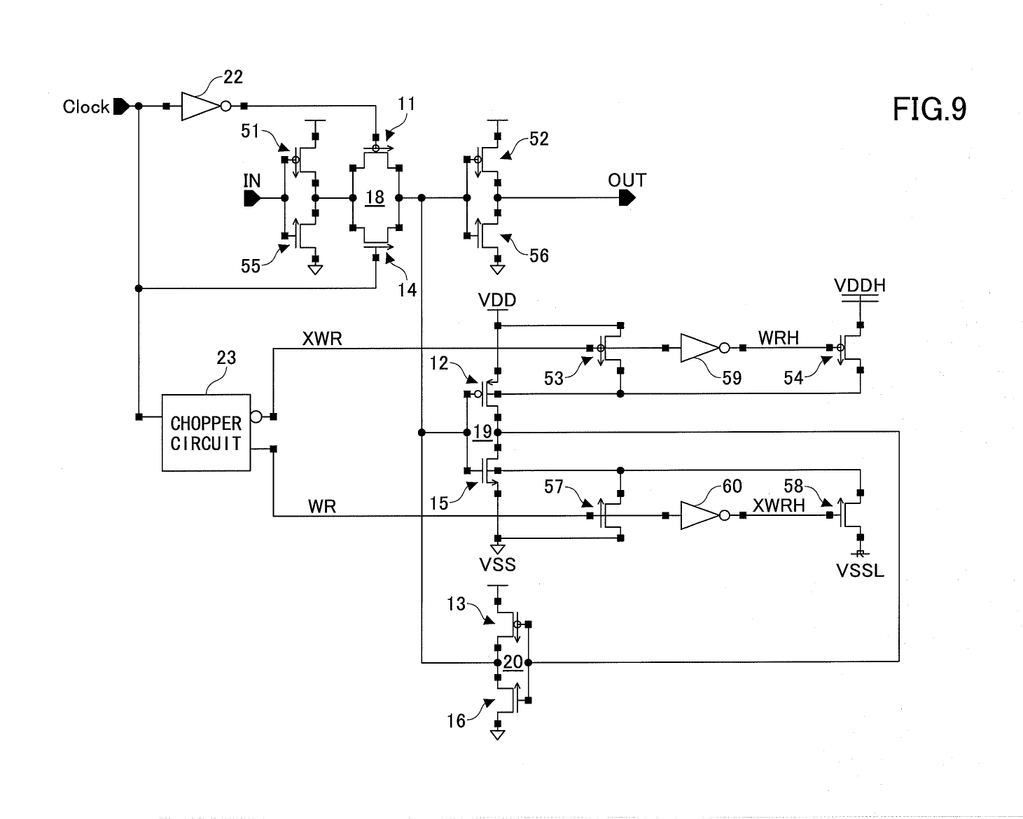

FIG. 9 is a drawing illustrating a specific example of the circuit configuration of the semiconductor integrated circuit illustrated in FIG. 8. In FIG. 9, the same or corresponding elements as those of FIG. 8 are referred to by the same or corresponding numerals, and a description thereof will be omitted as appropriate. The semiconductor integrated circuit illustrated in FIG. 9 includes PMOS transistors 11 through 13, NMOS transistors 14 through 16, the inverter 22, the chopper circuit 23, PMOS transistors 51 through 54, NMOS transistors 55 through 58, and level converters 59 and 60. The PMOS transistor 51 and the NMOS transistor 55 together function as a data-input-purpose inverter, and the PMOS transistor 52 and the NMOS transistor 56 together function as a data-output-purpose inverter.

The chopper circuit 23 generates the back-gate-voltage control signals WR and XWR. The back-gate-voltage control signals WR and XWR are HIGH and LOW, respectively, during at least part of the write-operation period, and LOW and HIGH, respectively, during at least part of the read-operation period. The back-gate-voltage control signal WR output from the chopper circuit 23 is applied to the gate of the NMOS transistor 57 and to the input of the level converter 60. The level converter 60 inverts the logic of the back-gate-voltage control signal WR, and lower the voltage level thereof to generate the back-gate-voltage control signal XWRH. The back-gate-voltage control signal XWRH is applied to the gate of the NMOS transistor 58. The source nodes of the NMOS transistors 57 and 58 are coupled to the ground potential and to the stepped-down voltage VSSL (<VSS). The level converter 60 serves to generate the voltage VSSL lower than VSS in order to properly make the NMOS transistor 58 nonconductive during the write operation. The back-gate-voltage control signals WR and XWRH control the conductive and nonconductive states of the NMOS transistors 57 and 58, respectively, thereby controlling the back-gate voltage of the NMOS transistor 15.

The back-gate-voltage control signal XWR output from the chopper circuit 23 is applied to the gate of the PMOS transistor 53 and to the input of the level converter 59. The level converter 59 inverts the logic of the back-gate-voltage control signal XWR, and raises the voltage level thereof to generate the back-gate-voltage control signal WRH. The back-gate-voltage control signal WRH is applied to the gate of the PMOS transistor 54. The source nodes of the PMOS transistors 53 and 54 are coupled to the power supply voltage VDD and to the stepped-up voltage VDDH (>VDD). The level converter 59 serves to generate the voltage VDDH higher than VDD in order to properly make the PMOS transistor 54 nonconductive during the write operation. The back-gate-voltage control signals XWR and WRH control the conductive and nonconductive states of the PMOS transistors 53 and 54, respectively, thereby controlling the back-gate voltage of the PMOS transistor 12.

The chopper circuit 23 generates the back-gate-voltage control signals WR and XWR based on the clock signal Clock, so that the semiconductor integrated circuit illustrated in FIG. 9 performs the same or similar operations as the operations illustrated in FIG. 3. Namely, the back-gate voltage of a transistor in the first inverter 19 is reverse-biased to increase the threshold voltage of the transistor during the read-operation period of the latch circuit. Such an increase in the threshold voltage provided by a reverse bias during the read-operation period can increase tolerance to power supply noise during the read-operation period. Further, during the write-operation period of the latch circuit, the normal threshold voltage without a bias effect is used to provide a high-speed write operation. Further, the time at which the reverse-biased back-gate voltage is applied may be set slightly earlier than the start time of the read-operation period, thereby utilizing the increased threshold voltage during the entirety of the read-operation period.

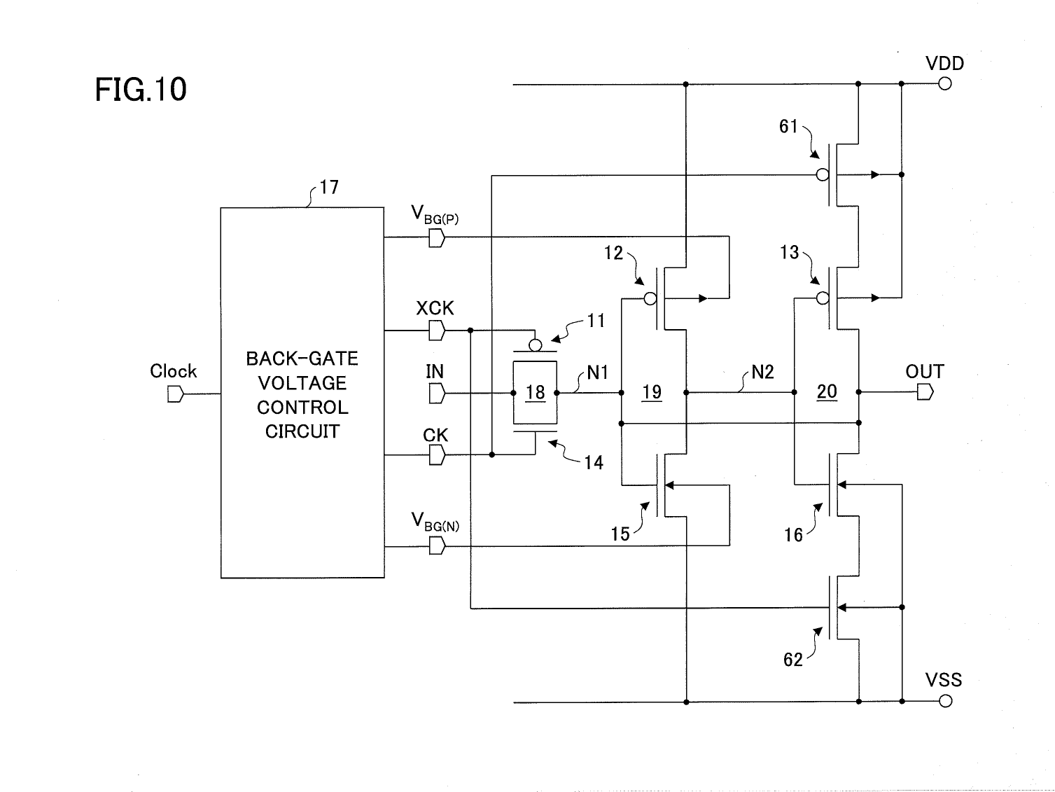

FIG. 10 is a drawing illustrating a variation of the configuration of the semiconductor integrated circuit illustrated in FIG. 1. In FIG. 10, the same or corresponding elements as those of FIG. 1 are referred to by the same or corresponding numerals, and a description thereof will be omitted as appropriate. In FIG. 10, a PMOS transistor 61 is series-connected to the power-supply voltage side of the second inverter 20, and an NMOS transistor 62 is series-connected to the ground voltage side of the second inverter 20. The transfer control signal CK is applied to the gate of the PMOS transistor 61, and the transfer control signal XCK is applied to the gate of the NMOS transistor 62. The second inverter 20 inclusive of the PMOS transistor 61 and the NMOS transistor 62 functions as a clocked inverter.

With the use of back-gate-voltage control, a slow change in the threshold voltage brings about a period during which the write speed drops during the write-operation period as illustrated in FIG. 3. In consideration of this, as illustrated in FIG. 10, a clocked inverter is used as the second inverter, and the second inverter 20 serving as a load is separated from the first inverter 19 to improve write performance. The use of a clocked inverter as the second inverter can provide satisfactory high-speed write performance while utilizing back-gate-voltage control to provide tolerance to power supply noise.

FIG. 11 is a drawing illustrating a variation of the configuration of the back-gate-voltage control circuit. In FIG. 11, the same or corresponding elements as those of FIG. 2 are referred to by the same or corresponding numerals, and a description thereof will be omitted as appropriate. A back-gate-voltage control circuit 17A illustrated in FIG. 11 differs from the back-gate-voltage control circuit 17 illustrated in FIG. 2 in that the chopper circuit 23 is not provided. Such a back-gate-voltage control circuit 17A may be used in place of the back-gate-voltage control circuit 17 illustrated in FIG. 1 and FIG. 10.

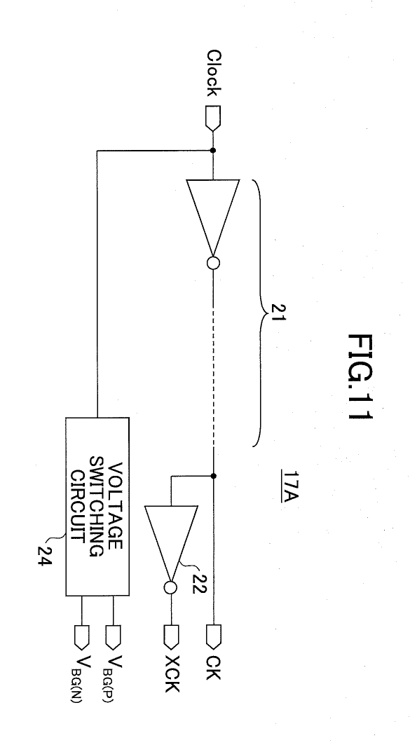

FIG. 12 is a drawing illustrating an example of the operation of the semiconductor integrated circuit illustrated in FIG. 1 when the back-gate-voltage control circuit 17A is used. In an example of the operation illustrated in FIG. 12, the back-gate voltages V_{BG(P)} and V_{BG(N)} are set equal to the respective source voltages (i.e., VDD and VSS) during the entirety of the write-operation period. Further, the back-gate voltages V_{BG(P)} and V_{BG(N)} are set equal to the respective reverse-biased voltages (i.e., VDDH and VSSL) during the entirety of the read-operation period. In this case, the transistor threshold voltages VTH(P) and VTH(N) have not become sufficiently large at the beginning part RS of the read-operation period. If power supply noise occurs during this beginning part RS, the data of the latch circuit may be inverted. In such a case, the erroneous inverted data is kept during almost the entirety of the read-operation period, thereby causing malfunctioning in subsequent operation stages.

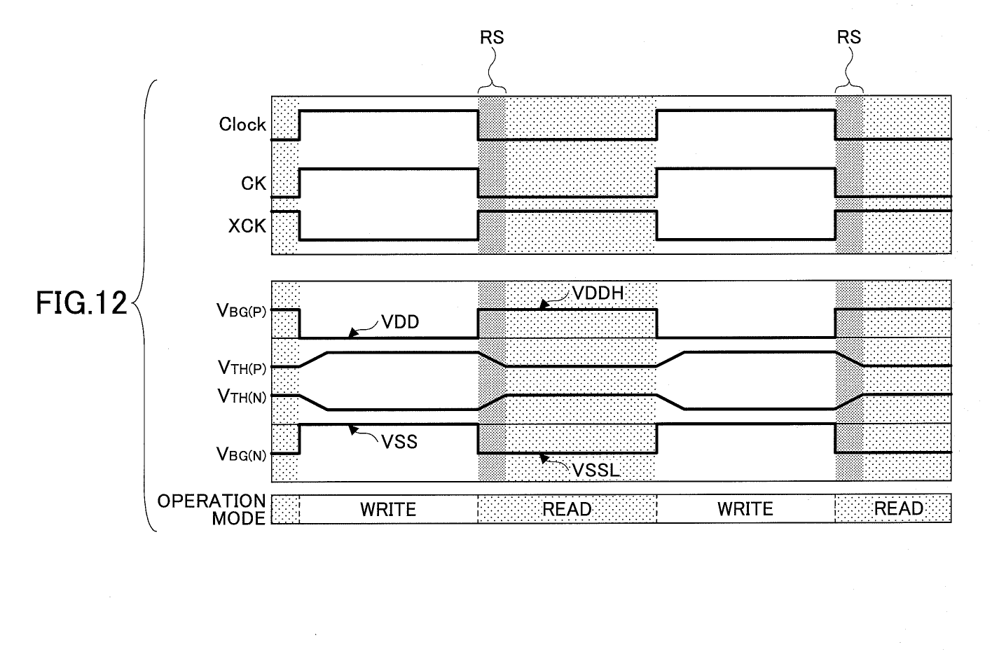

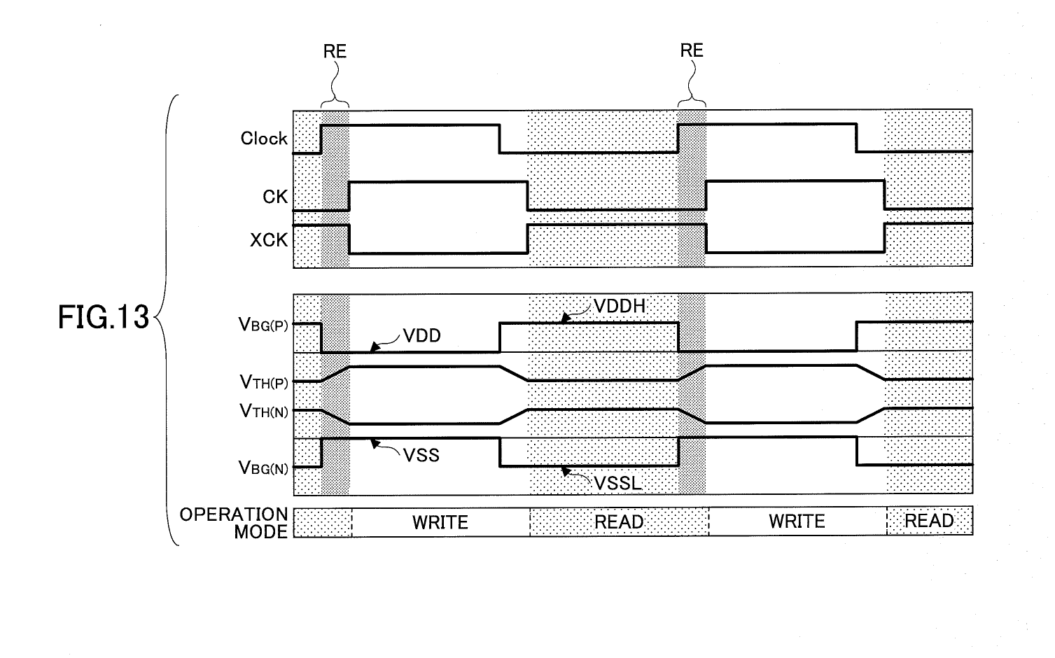

FIG. 13 is a drawing illustrating another example of the operation of the semiconductor integrated circuit illustrated in FIG. 1 when the back-gate-voltage control circuit 17A is used. In an example of the operation illustrated in FIG. 13, the delay of the one or more inverters 21 is set equal to a substantially long length, so that the occurrence of edges of the transfer control signals CK and XCK is delayed relative to the occurrence of changes of the back-gate voltage V_{BG(P)} and V_{BG(N)}. With this arrangement, the time period during which the transistor threshold voltages VTH(P) and VTH(N) have not become sufficiently large is in existence at the ending part RE of the read-operation period. If power supply noise occurs during this ending part RE, the data of the latch circuit may be inverted. However, the reversal of data occurs only at the ending part of the read-operation period. Correct data is kept during the period preceding RE wherein such a period accounts for almost the entirety of the read-operation period.

In general, the back-gate voltage may be kept at the source voltage during at least part of the write-operation period, and the back-gate voltage may be kept at the reverse-biased voltage during at least part of the read-operation period. In the example illustrated in FIG. 13, the back-gate voltage is kept at the source voltage during at least an early part of the write-operation period, and the back-gate voltage is kept at the reverse-biased voltage during at least an early part of the read-operation period. Performing a write operation in the early part of the write-operation period ensures high-speed writing, and performing a read operation in the early part of the read-operation period ensures correct data reading not affected by power supply noise.

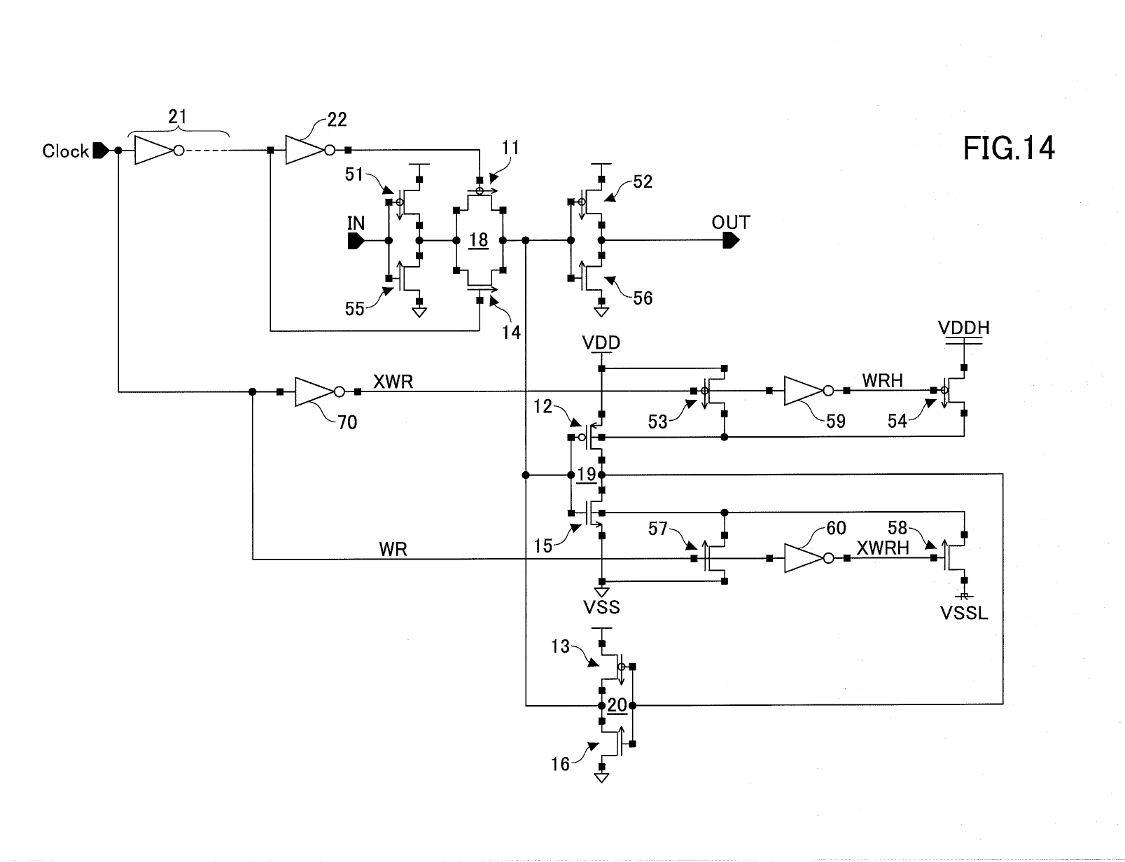

FIG. 14 is a drawing illustrating a specific example of the circuit configuration when the back-gate-voltage control circuit 17A illustrated in FIG. 11 is used in FIG. 1. In FIG. 14, the same or corresponding elements as those of FIG. 9 are referred to by the same or corresponding numerals, and a description thereof will be omitted as appropriate. Compared with the configuration of FIG. 9, the configuration of FIG. 14 is such that the chopper circuit 23 is removed, and an inverter 70 is provided as part of the voltage switching circuit 24. In FIG. 14, the one or more inverters 21 are provided on the input side of the inverter 22.

In this case, the length of the write-operation period is equal to the length of the period during which the back-gate voltage is set equal to the source voltage. Further, the length of the read-operation period is equal to the length of the period during which the back-gate voltage is placed in the reverse-biased condition. It may be noted that the provision of a long delay by use of the one or more inverters 21 makes it possible to provide a time period during which the transistor threshold voltages have not become sufficiently large during the read-operation period, and to place such a time period at the ending part RE of the read-operation period.

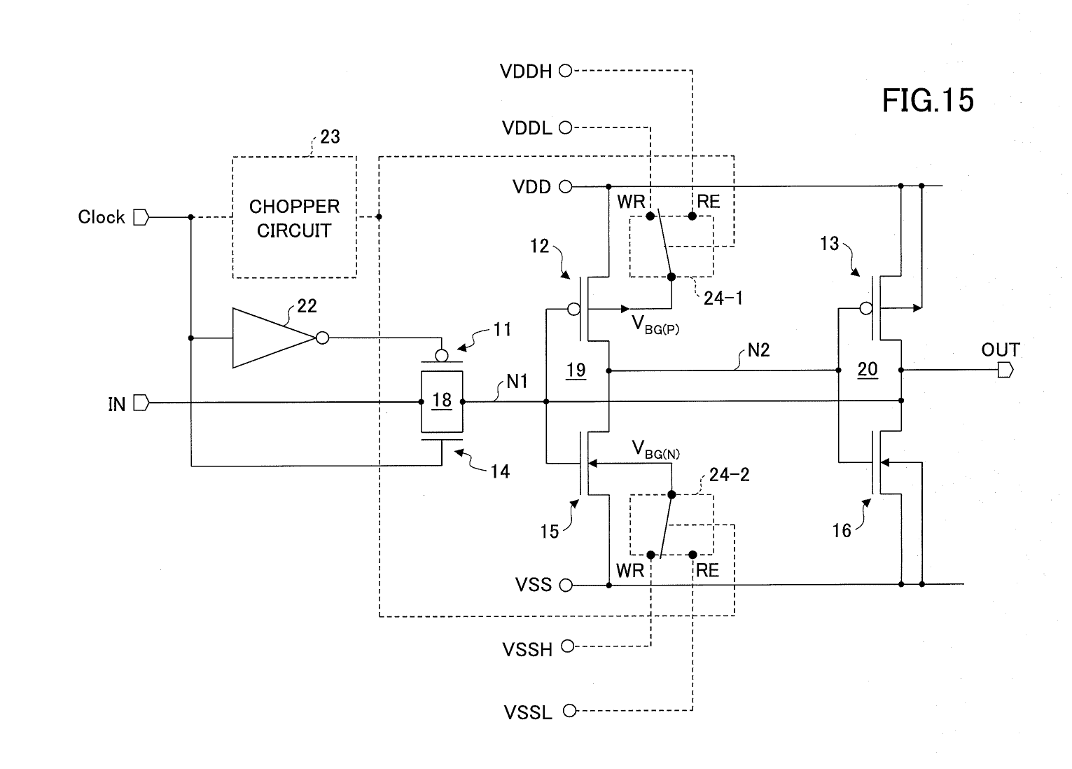

FIG. 15 is a drawing illustrating a variation of the semiconductor integrated circuit illustrated in FIG. 8. In FIG. 15, the same or corresponding elements as those of FIG. 8 are referred to by the same or corresponding numerals, and a description thereof will be omitted as appropriate. The constituent elements of the semiconductor integrated circuit illustrated in FIG. 15 are basically the same as or similar to the constituent elements of the semiconductor integrated circuit illustrated in FIG. 8. In the semiconductor integrated circuit illustrated in FIG. 15, however, the back-gate voltage is switched between the forward-bias state and the reverse-bias state. The back-gate voltage V_{BG(P)} of the PMOS transistor 12 is set equal to VDDL by the switch circuit 24-1 during the write operation, and is set equal to VDDH during the read operation. The back-gate voltage V_{BG(N)} of the NMOS transistor 15 is set equal to VSSH by the switch circuit 24-2 during the write operation, and is set equal to VSSL during the read operation. Here, the following conditions are satisfied: VDDL<VDD<VDDH, and VSSL<VSS<VSSH. Namely, VDDL is a forward-biased voltage relative to the source voltage VDD of the PMOS transistor 12. Further, VSSH is a forward-biased voltage relative to the source voltage VSS of the NMOS transistor 15.

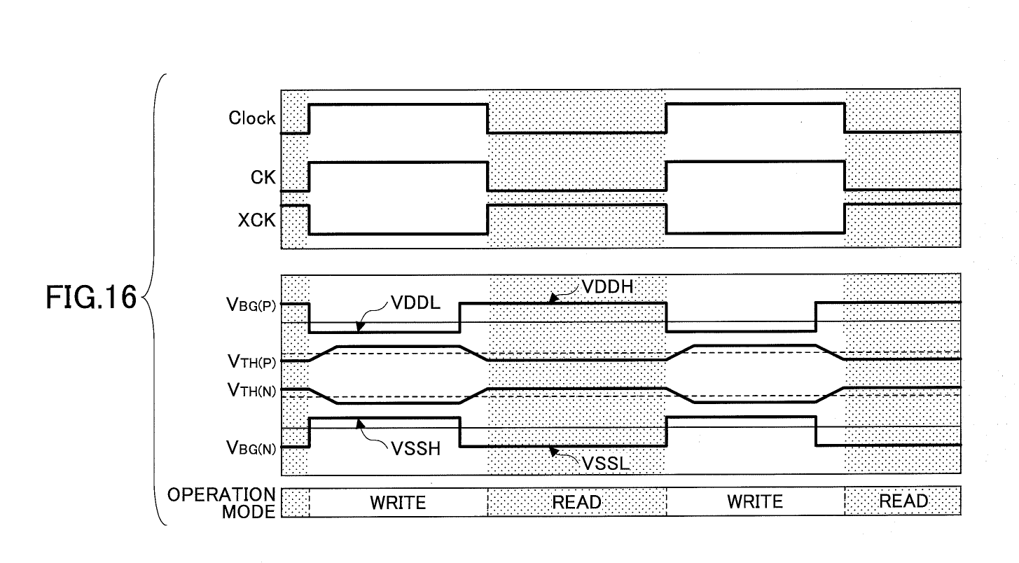

FIG. 16 is a drawing illustrating an example of the operation of the semiconductor integrated circuit illustrated in FIG. 15. During the write operation period, the back-gate voltage V_{BG(P)} of the PMOS transistor 12 of the first inverter 19 is set equal to the forward-biased voltage VDDL (<VDD) as illustrated in FIG. 16. Further, the back-gate voltage V_{BG(N)} of the NMOS transistor 15 of the first inverter 19 is set equal to the forward-biased voltage VSSH (>VSS). Accordingly, the respective threshold voltages V_{TH(P)} and V_{TH(N)} of the PMOS transistor 12 and the NMOS transistor 15 are decreased by the bias effect (i.e., are set equal to voltages whose differences from the respective source potentials are decreased).

During the read-operation period, the back-gate voltage V_{BG(P)} of the PMOS transistor 12 of the first inverter 19 is set equal to the reverse-biased voltage VDDH (>VDD) as illustrated in FIG. 16. Further, the back-gate voltage V_{BG(N)} of the NMOS transistor 15 of the first inverter 19 is set equal to the reverse-biased voltage VSSL (<VSS). Accordingly, the respective threshold voltages V_{TH(P)} and V_{TH(N)} of the PMOS transistor 12 and the NMOS transistor 15 are increased by the bias effect (i.e., are set equal to voltages whose differences from the respective source potentials are increased).

In this manner, the back-gate voltage of a transistor in the first inverter 19 is reverse-biased to increase the threshold voltage of the transistor during the read-operation period of the latch circuit. Such an increase in the threshold voltage provided by a reverse bias during the read-operation period can increase tolerance to power supply noise during the read-operation period. Further, during the write-operation period of the latch circuit, the forward-biased threshold voltage is used to provide a high-speed write operation.

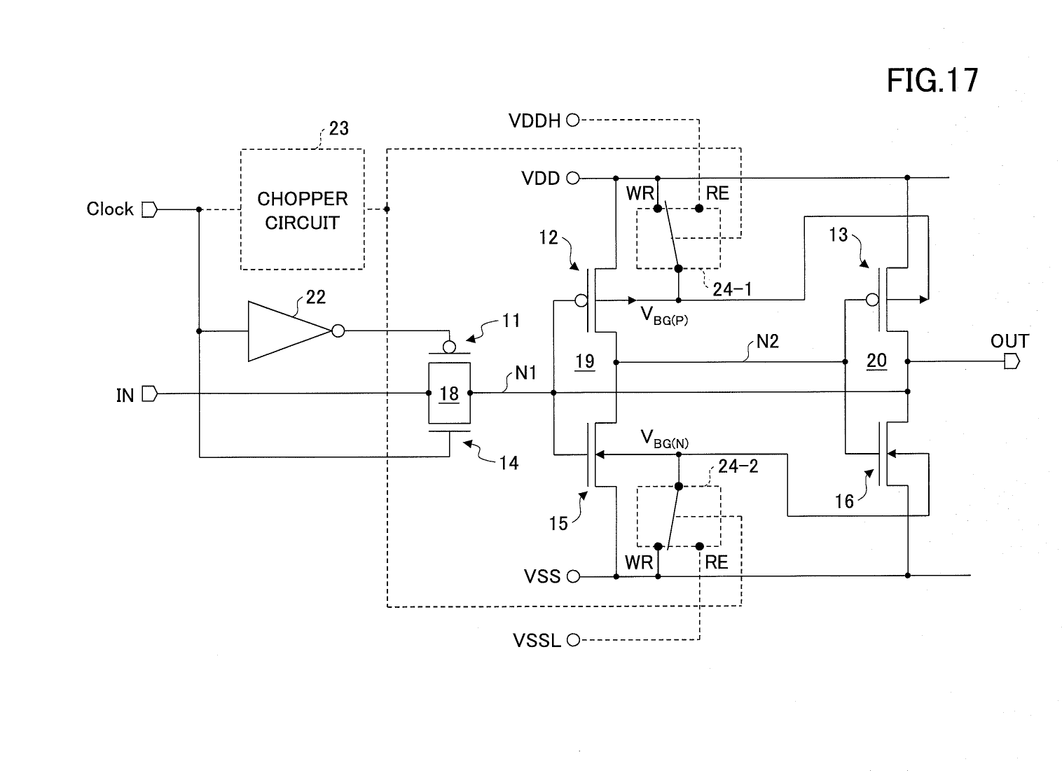

FIG. 17 is a drawing illustrating another variation of the semiconductor integrated circuit illustrated in FIG. 8. In FIG. 17, the same or corresponding elements as those of FIG. 8 are referred to by the same or corresponding numerals, and a description thereof will be omitted as appropriate. The constituent elements of the semiconductor integrated circuit illustrated in FIG. 17 are basically the same as or similar to the constituent elements of the semiconductor integrated circuit illustrated in FIG. 8. In the semiconductor integrated circuit illustrated in FIG. 17, however, the back-gate voltages of the transistors of the second inverter 20 are controlled in response to the synchronizing signal Clock similarly to the manner in which the back-gate voltages of the transistors of the first inverter 19 are controlled. Namely, the back-gate voltage of at least one transistor 13 or 16, which is included in the second inverter 20 and which has the gate node thereof connected to the second node N2 and the drain node thereof connected to the first node N1, is changed at the timing responsive to the synchronizing signal Clock.

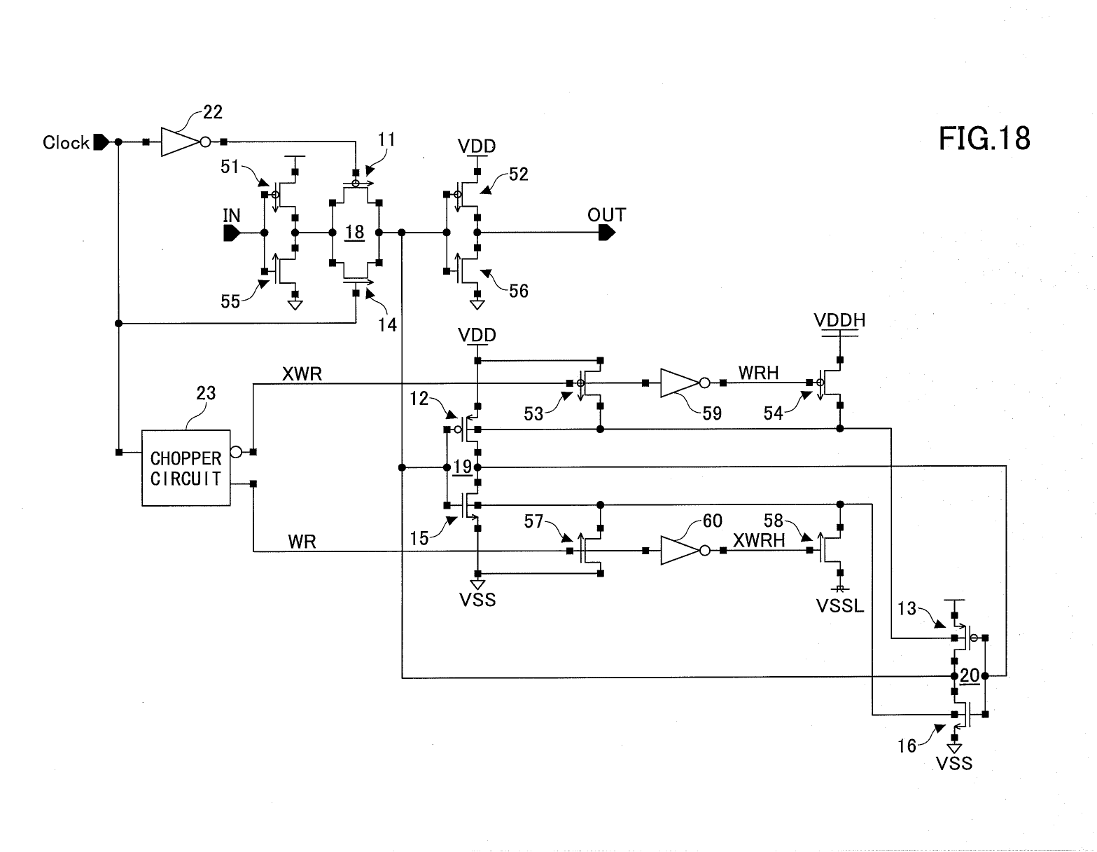

FIG. 18 is a drawing illustrating a specific example of the circuit configuration of the semiconductor integrated circuit illustrated in FIG. 17. In FIG. 18, the same or corresponding elements as those of FIG. 9 and FIG. 17 are referred to by the same or corresponding numerals, and a description thereof will be omitted as appropriate. The source nodes of the NMOS transistors 57 and 58 are coupled to the ground potential and to the stepped-down voltage VSSL (<VSS). The back-gate-voltage control signals WR and XWRH control the conductive and nonconductive states of the NMOS transistors 57 and 58, respectively, thereby controlling the back-gate voltages of the NMOS transistor 15 of the first inverter 19 and the NMOS transistor 16 of the second inverter 20. Further, the source nodes of the PMOS transistors 53 and 54 are coupled to the power supply voltage VDD and to the stepped-up voltage VDDH (>VDD). The back-gate-voltage control signals XWR and WRH control the conductive and nonconductive states of the PMOS transistors 53 and 54, respectively, thereby controlling the back-gate voltages of the PMOS transistor 12 of the first inverter 19 and the PMOS transistor 13 of the second inverter 20.

The use of the circuit configuration as illustrated in FIG. 17 and FIG. 18 makes it possible to share a well between the first inverter 19 and the second inverter 20. In the circuit configuration illustrated in FIG. 8 and FIG. 9, for example, the back-gate voltages of the first inverter 19 are variably controlled, and the back-gate voltages of the second inverter 20 are fixed. In such a case, the first inverter 19 and the second inverter 20 are formed in separate wells. On the other hand, when the back-gate voltages of the first inverter 19 and the second inverter 20 are variably controlled in the same manner, the first inverter 19 and the second inverter 20 can be formed in the same well. This allows the layout area size of the circuit to be reduced.

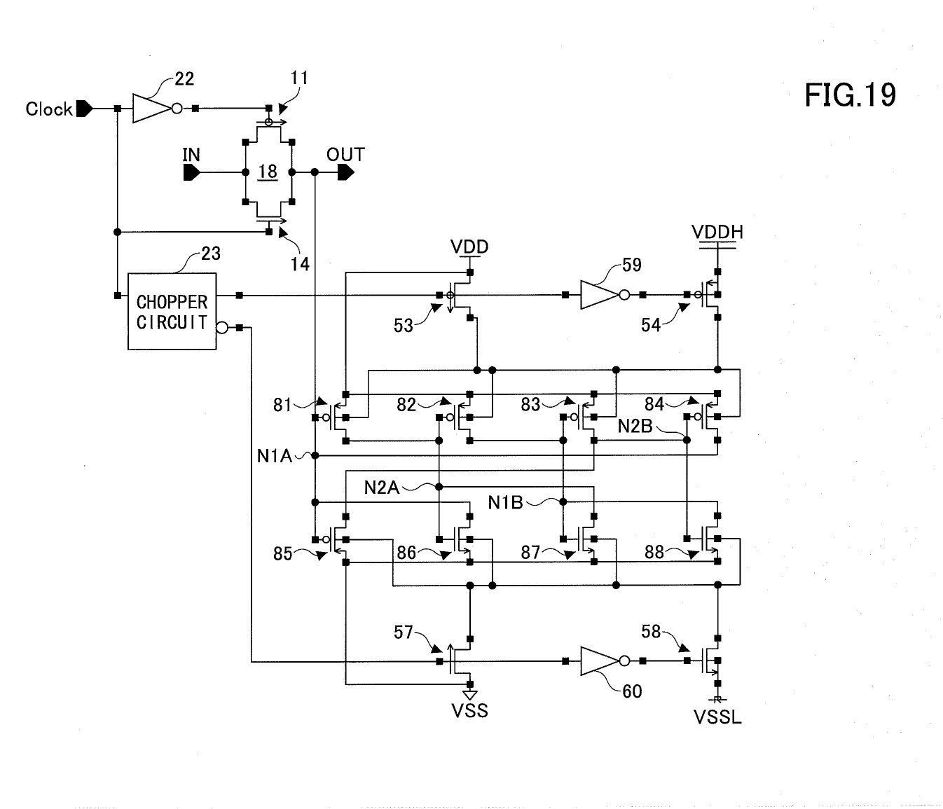

FIG. 19 is a drawing illustrating an example of the configuration of the semiconductor integrated circuit in which a Dice latch is used as the latch circuit. In FIG. 19, the same or corresponding elements as those of FIG. 9 are referred to by the same or corresponding numerals, and a description thereof will be omitted as appropriate. The semiconductor integrated circuit illustrated in FIG. 19 includes the PMOS transistor 11, the NMOS transistor 14, the inverter 22, the chopper circuit 23, the PMOS transistors 53 and 54, the NMOS transistors 57 and 58, PMOS transistors 81 through 84, and NMOS transistors 85 through 88.

The Dice (dual interlocked storage cell) latch is similar to a conventional latch in that two inverters are connected to each other such that the outputs thereof are connected to the inputs of each other, but each of the inverters is a dual-port inverter having two inputs and two outputs. Such a configuration serves to significantly reduce the rate of soft error occurrences. In FIG. 19, the PMOS transistors 81 and 83 and the NMOS transistors 85 and 17 together function as a first inverter (i.e., a dual-port inverter having two inputs and two outputs). The PMOS transistor 81 and the NMOS transistor 87 are series-connected, and the PMOS transistor 83 and the NMOS transistor 85 are series-connected. The gate node of the PMOS transistor 81 and the gate node of the NMOS transistor 85 are connected to a first node N1A, and the gate node of the PMOS transistor 83 and the gate node of the NMOS transistor 87 are connected to another first node N1B. Either one of the first nodes N1A and N1B can serve as an input and output node. In this example, the first node N1A is used as the input and output node.

Further, the PMOS transistors 82 and 84 and the NMOS transistors 86 and 88 together function as a second inverter (i.e., a dual-port inverter having two inputs and two outputs). The PMOS transistor 82 and the NMOS transistor 88 are series-connected, and the PMOS transistor 84 and the NMOS transistor 86 are series-connected. The gate node of the PMOS transistor 82 and the gate node of the NMOS transistor 86 are connected to a second node N2A, and the gate node of the PMOS transistor 84 and the gate node of the NMOS transistor 88 are connected to another second node N2B.

The first inverter has two inputs thereof connected to the two first nodes N1A and N1B, and has two outputs thereof connected to the two second nodes N2A and N2B. The second inverter has two inputs thereof connected to the two second nodes N2A and N2B, and has two outputs thereof connected to the two first nodes N1A and N1B.

In the Dice latch having the configuration described above, the back-gate voltage of at least one transistor in the inverters included in the latch circuit may be changed at the timing responsive to the synchronizing signal Clock. In the example illustrated in FIG. 19, back-gate voltages are controlled with respect to the four transistors of the first inverter and the four transistors of the second inverter included in the latch circuit. Namely, a transfer control signal from the chopper circuit 23 controls the conductive and nonconductive states of the NMOS transistors 57 and 58, thereby controlling the back-gate voltages of the NMOS transistors 85 through 88. Further, a transfer control signal from the chopper circuit 23 controls the conductive and nonconductive states of the PMOS transistors 53 and 54, thereby controlling the back-gate voltages of the PMOS transistors 81 through 84.

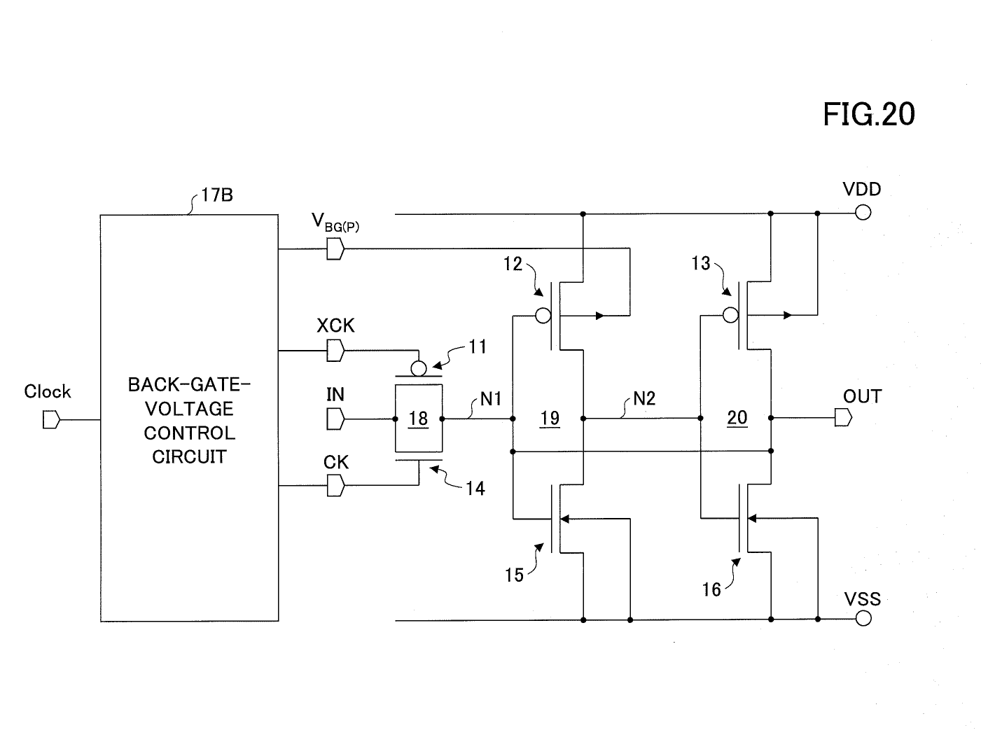

FIG. 20 is a drawing illustrating an example of the configuration of a variation of the semiconductor integrated circuit illustrated in FIG.

1. In FIG. 20, the same or corresponding elements as those of FIG. 1 are referred to by the same or corresponding numerals, and a description thereof will be omitted as appropriate. In FIG. 1, the back-gate-voltage control circuit 17 controls the back-gate voltages of both the PMOS transistor 12 and the NMOS transistor 15 of the first inverter 19. In FIG. 20, on the other hand, a back-gate-voltage control circuit 17B controls only the back-gate voltage of the PMOS transistor 12 of the first inverter 19. Namely, provision is made such that the back-gate voltage of the NMOS transistor 15 of the first inverter 19 is fixed. Other configurations and operations are the same as or similar to those of the semiconductor integrated circuit illustrated in FIG. 1.

The circuit configuration illustrated in

FIG. 20 is effective when the latch circuit holds a HIGH level for a long time. When the latch circuit holds a HIGH level, the output of the first inverter 19 is LOW, and the output of the second inverter 20 is HIGH. In this state, power supply noise may be introduced into the ground voltage VSS to raise the output of the first inverter 19, thereby lowering the output voltage of the second inverter 20. In such a case, during the read-operation period, the threshold voltage of the PMOS transistor 12 is increased, so that the first inverter 19 is not likely to be inverted. Proper tolerance to power supply noise is thus attained. Similarly, provision may be made such that when the latch circuit holds a LOW level for a long time, only the back-gate voltage of the NMOS transistor 15 of the first inverter 19 is controlled.

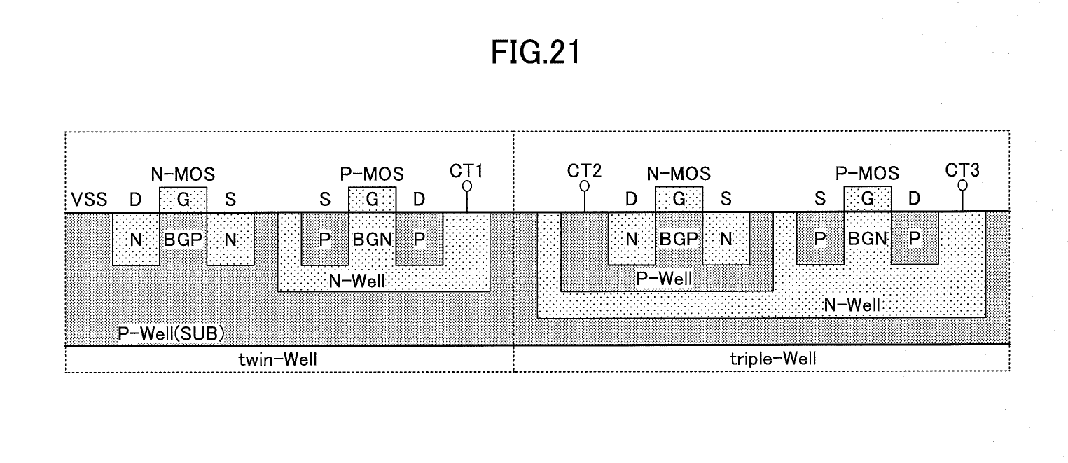

Further, the configuration illustrated in FIG. 20 has merit in that the circuit can be implemented by use of a twin-well structure rather than a triple-well structure. FIG. 21 is a drawing illustrating a triple-well structure and a twin-well structure in comparison with each other. The twin-well structure is illustrated on the left-hand side of the figure, and the triple-well structure is illustrated on the right-hand side of the figure. The configuration in which back-gate voltages are controlled with respect to both the PMOS transistor and the NMOS transistor as illustrated in FIG. 1 uses the triple-well structure as illustrated on the right-hand side of FIG. 21. In this case, the back-gate voltage of the NMOS transistor (i.e., the potential of the P well) is controlled via a control node CT2, and the back-gate voltage of the PMOS transistor (i.e., the potential of the N well) is controlled via a control node CT3. On the other hand, the use of the twin-well structure as illustrated on the left-hand side of FIG. 21 suffices for the configuration in which a back-gate voltage is controlled only with respect to the PMOS transistor as illustrated in FIG. 20. In this case, the back-gate voltage of the PMOS transistor (i.e., the potential of the N well) is controlled via a control node CT1.

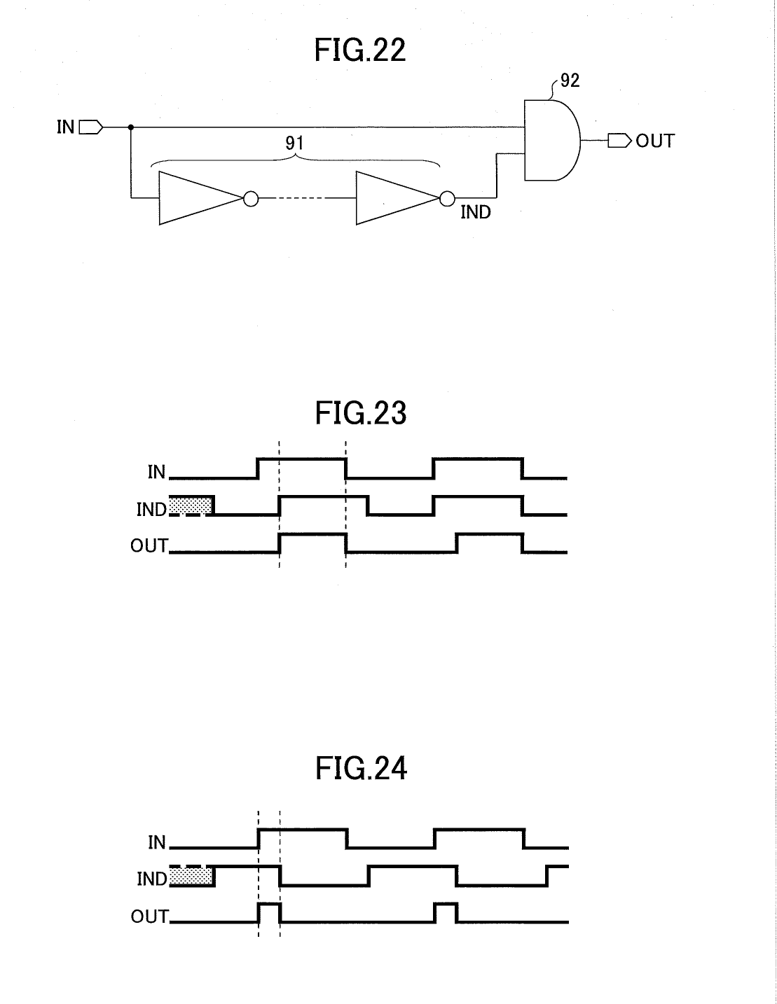

FIG. 22 is a drawing illustrating an example of the configuration of a chopper circuit. The chopper circuit illustrated in FIG. 22 includes one or more inverters 91 and an AND gate 92. The one or more inverters 91 serving as a line of delay elements delay an input signal IN, and the AND gate 92 performs an AND operation between the delayed signal IND and the delay-free input signal IN, thereby adjusting the pulse width of the input signal IN.

FIG. 23 is a drawing illustrating an example of the operation of the chopper circuit illustrated in FIG. 22. FIG. 23 illustrates the operation observed when the number of inverters 91 is even. An AND operation between the input signal IN and the signal IND obtained by delaying the input signal IN produces an output OUT. In this case, a HIGH pulse is obtained by extracting a latter part of the corresponding HIGH pulse of the input signal IN.

FIG. 24 is a drawing illustrating another example of the operation of the chopper circuit illustrated in FIG. 22. FIG. 24 illustrates the operation observed when the number of inverters 91 is odd. An AND operation between the input signal IN and the signal IND obtained by delaying the input signal IN produces an output OUT. In this case, a HIGH pulse is obtained by extracting an early part of the corresponding HIGH pulse of the input signal IN.

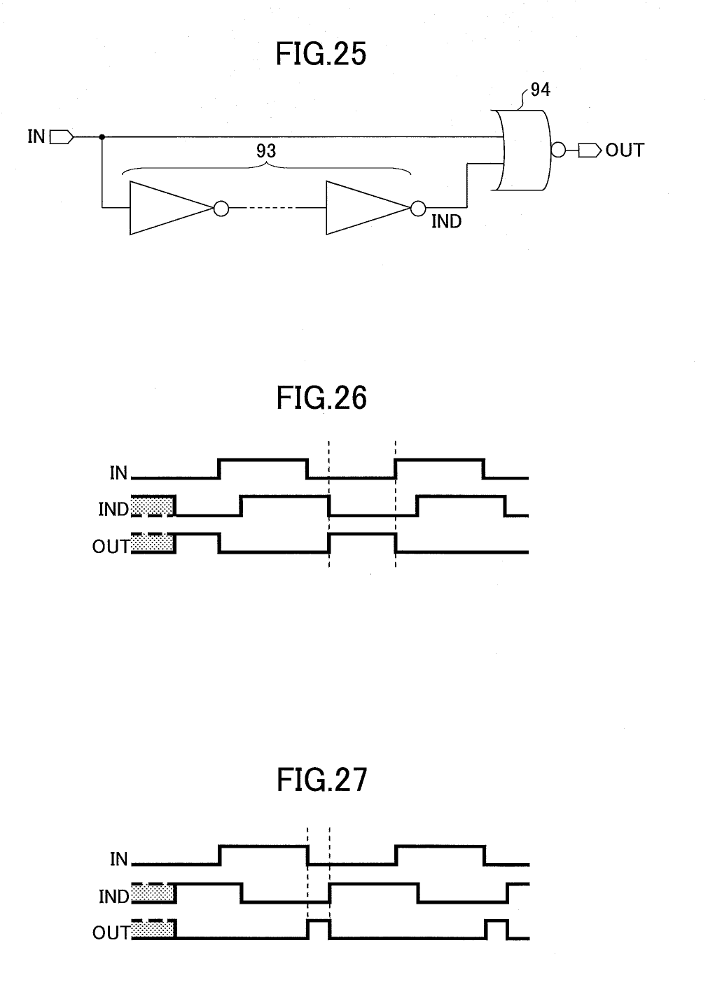

FIG. 25 is a drawing illustrating another example of the configuration of a chopper circuit. The chopper circuit illustrated in FIG. 25 includes one or more inverters 93 and a NOR gate 94. The one or more inverters 93 serving as a line of delay elements delay an input signal IN, and the NOR gate 94 performs a NOR operation between the delayed signal IND and the delay-free input signal IN, thereby adjusting the pulse width of the input signal IN.

FIG. 26 is a drawing illustrating an example of the operation of the chopper circuit illustrated in FIG. 25. FIG. 26 illustrates the operation observed when the number of inverters 93 is even. A NOR operation between the input signal IN and the signal IND obtained by delaying the input signal IN produces an output OUT. In this case, a HIGH pulse is obtained by extracting a latter part of the corresponding LOW pulse of the input signal IN.

FIG. 27 is a drawing illustrating another example of the operation of the chopper circuit illustrated in FIG. 25. FIG. 27 illustrates the operation observed when the number of inverters 93 is odd. A NOR operation between the input signal IN and the signal IND obtained by delaying the input signal IN produces an output OUT. In this case, a HIGH pulse is obtained by extracting an early part of the corresponding LOW pulse of the input signal IN.

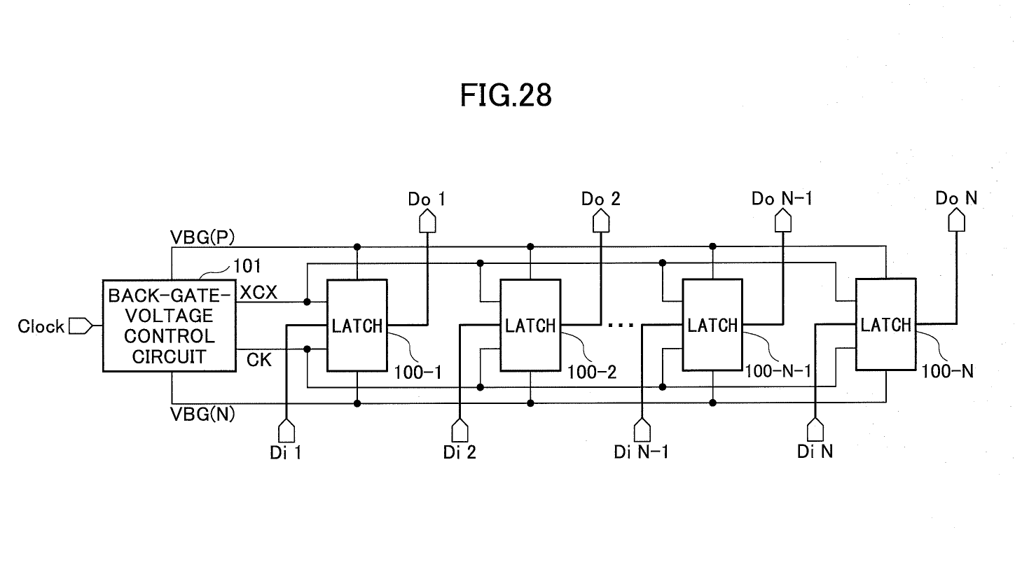

FIG. 28 is a drawing illustrating an example of the configuration in which back-gate-voltage control is applied to a plurality of latch circuits. In FIG. 28, a back-gate-voltage control circuit 101 may be the back-gate-voltage control circuit 17 or 17B previously described. Alternatively, the back-gate-voltage control circuit 101 may be a circuit (e.g., 17B illustrated in FIG. 20) that controls a back-gate voltage of either a PMOS side or an NMOS side.

In the circuit configuration illustrated in FIG. 28, a plurality of latch circuits 100-1 through 100-N are provided. The latch circuits 100-1 through 100-N have input terminals Di1 through DiN and output terminals Do1 through DoN, respectively, and stores N-bit data as a whole.

The back-gate-voltage control circuit 101 further changes the back-gate voltage of at least one transistor in the inverters included in each of the latch circuits 100-1 through 100-N at the timing responsive to the synchronizing signal Clock. In this case, the transistors subjected to the back-gate-voltage control in the latch circuits 100-1 through 100-N can be formed in a single well. Further, there may be a case in which the transistors subjected to the back-gate-voltage control in the latch circuits 100-1 through 100-N are formed in separate wells. Even in such a case, it is preferable that the same back-gate voltages V_{BG(P)} and V_{BG(N)} or the same back-gate-voltage control signals (e.g., WR, XWR, etc., illustrated in FIG. 9) are supplied to the latch circuits 100-1 through 100-N from the single back-gate-voltage control circuit 101.

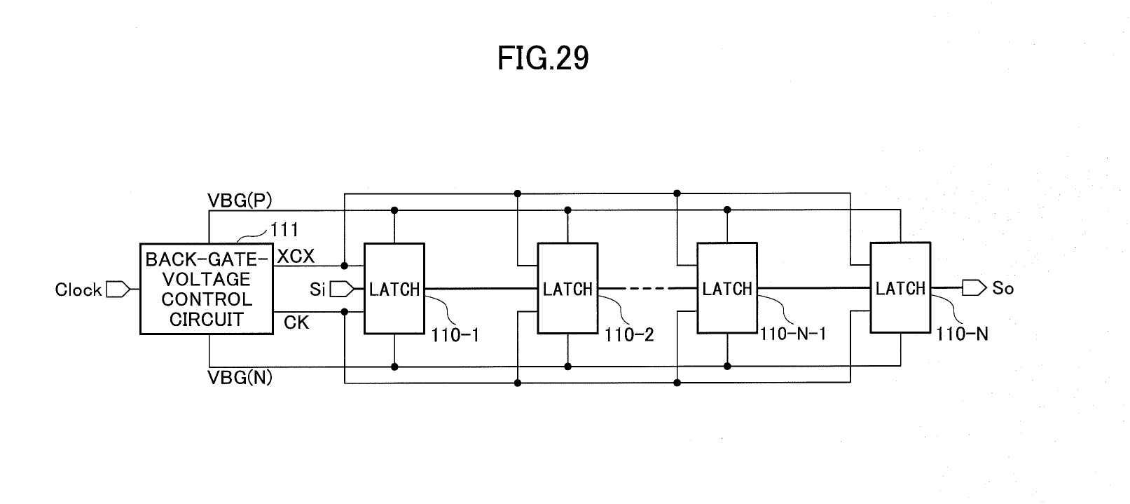

FIG. 29 is a drawing illustrating another example of the configuration in which back-gate-voltage control is applied to a plurality of latch circuits. In FIG. 29, a back-gate-voltage control circuit 111 may be the back-gate-voltage control circuit 17 or 17B previously described. Alternatively, the back-gate-voltage control circuit 101 may be a circuit (e.g., 17B illustrated in FIG. 20) that controls a back-gate voltage of either a PMOS side or an NMOS side.

In the circuit configuration illustrated in FIG. 29, a plurality of latch circuits 110-1 through 110-N are provided. The latch circuits 110-1 through 110-N are connected in cascade to form a shift register. The latch circuits 110-1 through 110-N may be scan flip-flops that form a scan chain. In this case also, similarly to the configuration illustrated in FIG. 28, the back-gate voltage of at least one transistor in the inverters included in each of the latch circuits 110-1 through 110-N may be changed at the timing responsive to the synchronizing signal Clock.

According to an embodiment, a semiconductor integrated circuit is provided in which tolerance to power supply noise is increased or in which the speed of a latch operation is increased.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

What is claimed is:

1. A semiconductor integrated circuit, comprising:
a latch circuit;
a data applying circuit configured to apply data to an input node of the latch circuit at timing responsive to a synchronizing signal; and
a back-gate-voltage control circuit configured to change a back-gate voltage of at least one transistor in an inverter included in the latch circuit at timing responsive to the synchronizing signal.

2. The semiconductor integrated circuit as claimed in claim 1, wherein the latch circuit includes:
a first inverter having an input thereof connected to a first node and an output thereof connected to a second node; and
a second inverter having an input thereof connected to the second node and an output thereof connected to the first node,
wherein the input node of the latch circuit is the first node, and
wherein the at least one transistor includes at least one transistor that is included in the first inverter and that has a gate node thereof connected to the first node and a drain node thereof connected to the second node.

3. The semiconductor integrated circuit as claimed in claim 1, wherein the data applying circuit applies a voltage corresponding to the data to the first node during a first period and applies no voltage to the first node during a second period, and wherein the back-gate-voltage control circuit keeps the back-gate voltage at a first voltage during at least part of the first period, and keeps the back-gate voltage at a second voltage that is a reverse-biased voltage during at least part of the second period.

4. The semiconductor integrated circuit as claimed in claim 1, wherein the back-gate-voltage control circuit keeps the back-gate voltage at the first voltage during at least an early part of the first period, and keeps the back-gate voltage at the second voltage during at least an early part of the second period.

5. The semiconductor integrated circuit as claimed in claim 1, wherein the back-gate-voltage control circuit is configured to set the back-gate voltage equal to the first voltage during at least an early part of the first period, to change the back-gate voltage from the first voltage to the second voltage during the first period, and to keep the back-gate voltage at the second voltage during an entirety of the second period.

6. The semiconductor integrated circuit as claimed in claim 1, wherein the first voltage is a forward-biased voltage relative to a source voltage of the transistor.

7. The semiconductor integrated circuit as claimed in claim 1, wherein the back-gate-voltage control circuit changes, at timing responsive to the synchronizing signal, the back-gate voltage of at least one transistor that is included in the second inverter and that has a gate node thereof connected to the second node and a drain node thereof connected to the first node.

8. The semiconductor integrated circuit as claimed in claim 2, wherein the first node is a node set including two nodes, and the second node is a node set including two nodes, and wherein each of the first inverter and the second inverter is a dual-port inverter having two inputs and two outputs.

9. The semiconductor integrated circuit as claimed in claim 2, wherein the second inverter is a clocked inverter.

10. The semiconductor integrated circuit as claimed in claim 1, wherein the latch circuit is a set of latch circuits, and the back-gate-voltage control circuit is configured to change a back-gate voltage of at least one transistor in an inverter included in each of the latch circuits at timing responsive to the synchronizing signal.

11. A method of driving a latch circuit, comprising:
applying data to an input node of a latch circuit at timing responsive to a synchronizing signal; and
changing a back-gate voltage of at least one transistor in an inverter included in the latch circuit at timing responsive to the synchronizing signal.
